(19) United States
(12) Patent Application Publication
(10) Pub. No.: US 2008/0116549 A1
(43) Pub. Date: May 22, 2008

(54) TRANSMISSION TYPE PHOTO INTERRUPTER AND MANUFACTURING METHOD FOR SAME

(76) Inventor: Yohhei TSUKAHARA, Katsuragi-shi (JP)

Correspondence Address: BIRCH STEWART KOLASCH & BIRCH, PO BOX 747, FALLS CHURCH, VA, 22040-0747, US

(21) Appl. No.: 11/940,565

(22) Filed: Nov. 15, 2007

(30) Foreign Application Priority Data
Nov. 17, 2006 (JP) 2006-311347

(51) Int. Cl. H01L 23/495

(52) U.S. Cl. 257/676

(57) ABSTRACT

A transmission type photo interrupter has a light emitting element, a light receiving element, a lead frame, and a connector terminal, which are integrally molded with light-shielding resin. The light emitting chip and the light receiving chip are mounted on the same surface of the lead frame and rotated in the opposite directions each other so that face a light emitting chip in the light emitting element may face a light receiving chip in the light receiving element. This simplified structure of the transmission type photo interrupter reduces the number of assembly parts as well as assembly processes, which allow achievement of cost reduction.

### CROSS-REFERENCE TO RELATED APPLICATION

This nonprovisional application claims priority under 35 U.S.C. §119(a) on Patent Application No. 2006-311347 filed in Japan on 17 Nov. 2006, the entire contents of which are incorporated herein by reference.

### BACKGROUND OF THE INVENTION

The present invention relates to a transmission type photo interrupter which can detect presence of a subject to be detected without any contact, and relates to a manufacturing method for the same.

As a conventional transmission type photo interrupter, there has been such an optical coupling device as to have a structure as shown in FIG. 8 (JP 07-193272A). The structure of the optical coupling device disclosed in JP 07-193272A and the manufacturing procedure thereof with reference to FIG. 8 are as follows.

A light emitting chip 2 is mounted on a lead frame 1 and then bonded to be internally connected with wires such as gold wires, and is molded with translucent resin so as to form a light emitting element 3. A light receiving chip 4 is mounted on a same surface of the lead frame 1 as that of the light emitting chip 2, and is bonded to be internally connected with wires such as gold wires. The light receiving chip 4 is molded with translucent resin so as to form a light receiving element 5. Further, the lead frame 1 is provided with input/output terminals for connecting the light emitting element 3 and the light receiving element 5 to the outside devices. The input/output terminals are provided, as a connector joint section 6, at one end of the lead frame 1 in the direction of link between the light emitting element 3 and the light receiving element 5.

The lead frame 1, as mentioned above, on which the light emitting element 3 and the light receiving element 5 are formed, is folded and stood upright so that the light emitting chip 2 and the light receiving chip 4 may face each other. A connector 7 is set in the connector joint section 6 so as to heat-weld between the connector joint section 6 and a pin 8 of the connector 7. Further, the lead frame is housed in an armour folder 9 which has a window for allowing a light beam to pass through. Heat-welding pins 10 and 11 are provided in a bottom center section of the armour folder 9 and in a joint of the connector 7, respectively. The heat-welding pin 10 is inserted into a hole (not shown) provided in the lead frame 1. The heat-welding pin 11 is inserted in between a plurality of the connector joint sections 6. The armour folder 9 is secured to the lead frame 1 by heat-welding the pins 10 and 11. It is to be noted that the heat-welding pins 10 and 11 do not have the original shape of a pin in FIGS. 5A and 5B since they were already deformed by heat.

In the conventional optical coupling device (transmission type photo interrupter) disclosed in JP H07-193272A, assembly parts are composed of three parts: a lead frame 1 having the light emitting element 3 and light receiving element 5 formed thereon, a connector 7 and an armour folder 9. Therefore, there is a problem that the assembly parts are large in number and so the assembly process takes time and effort. Further, there is also a problem that during heat-welding of the pins 10 and 11, securing operation takes time and effort and generates burrs.

### BRIEF SUMMARY OF THE INVENTION

An object of the present invention is to provide a transmission type photo interrupter which reduces the number of assembly parts and thereby simplifies assembly process so as to achieve cost reduction.

In order to achieve the above-mentioned object, the present invention provides a transmission type photo interrupter, comprising:

a lead frame having a connector terminal;

a light emitting element having a light emitting chip and translucent resin, the light emitting chip being mounted on the lead frame, internally connected with the lead frame and sealed in the translucent resin; and

a light receiving element having a light receiving chip and translucent resin, the light receiving chip being mounted on the lead frame, internally connected with the lead frame and sealed in the translucent resin, wherein

the light emitting element, the light receiving element, the lead frame, and at least a part of the connector terminal are sealed with light-shielding resin so that the light emitting element, the light receiving element, the lead frame and the connector terminal are integrally molded.

According to present invention, the light emitting element, the light receiving element, the lead frame, and the connector terminal are integrally molded. Therefore, it becomes unnecessary to store the light emitting element, the light receiving element, the lead frame and the connector terminal in an armored case or an armour folder as in JP H07-193272A. Thus, the number of assembly parts can be reduced. Further, it becomes unnecessary to perform hot welding for securing the lead frame to the armored case or the armour folder. Therefore, the assembly process can be simplified. This leads to excellent mass production of the device. In other words, according to the present invention, the number of assembly parts can be reduced and thereby the assembly process can be simplified, so that cost reduction can be achieved.

The lead frame and a part of the connector terminal are all covered with light-shielding resin, so that the holding state of the lead frame and the connector can be strengthened more.

In one embodiment of the inventions the light emitting chip is mounted on a same surface of the lead frame as a surface thereof on which the light receiving chip is mounted, and the light emitting element and the light receiving element has been rotated in opposite directions each other with respect to the lead frame surface so as to stand upright on the same surface of the lead frame, so that the light emitting chip and the light receiving chip face each other.

According to this embodiment, the light emitting chip and the light receiving chip are mounted on the same surface of the lead frame. Therefore, it is not necessary to turn the lead frame over during mounting the light emitting chip and the light receiving chip on the lead frame. This makes it possible to mount the light emitting chip and the light receiving chip thereon at one time.

In one embodiment of the invention, the light emitting chip is mounted on an opposite surface of the lead frame to a surface thereof on which the light receiving chip is mounted, the light emitting element and the light receiving element have been rotated in a same direction with respect to the lead frame surface so as to stand upright on the same surface of the lead frame, so that the light emitting chip and the light receiving chip face each other.

According to this embodiment, the light emitting chip and the light receiving chip are mounted on the surfaces of the lead frame opposite to each other. The light emitting element and the light receiving element can be stood upright on the same surface of the lead frame by rotating them in the same direction with respect to the lead frame surface. This makes it possible to shorten an interval between the mounting positions of the light emitting chip and the light receiving chip in the state prior to folding (forming), as compared with the case where the light emitting element and the light receiving element are stood upright by rotating them in opposite directions to each other. Thereby the frame size of the lead frame can be reduced, which makes the device excellent in mass production.

Also, prior to the holding, it becomes possible to provide the light emitting element and the light receiving element on the same side with respect to the connector terminal. This makes it easily possible to approximately equalize a distance from the light emitting element to the folding position of the lead frame and a distance from the light receiving element to the folding position of the lead frame. As a result, the light emitting chip and the light receiving chip can face each other by easily setting the optical axes heights of the light emitting element and the light receiving element to a predetermined height when folding (forming).

In one embodiment of the invention, the light emitting chip is mounted on a same surface of the lead frame as a surface thereof on which the light receiving chip is mounted, the light emitting element and the light receiving element have been rotated in a same direction with respect to the lead frame surface so as to stand upright on the same surface of the lead frame, so that the light emitting chip and the light receiving chip face in a same direction.

According to this embodiment, the light emitting chip and the light receiving chip are mounted on the same surface of the lead frame. Therefore, it is not necessary to turn the lead frame over during mounting the light emitting chip and the light receiving chip on the lead frame. This makes it possible to mount the light emitting chip and the light receiving chip thereon at one time.

Also, the light emitting element and the light receiving element stand upright on the same surface of the lead frame by rotating them in the same direction with respect to the lead frame surface. This makes it possible to shorten an interval between the mounting positions of the light emitting chip and the light receiving chip in the state prior to folding (forming), as compared with the case where the light emitting element and the light receiving element are stood upright by rotating them in the opposite directions to each other. Thereby the frame size of the lead frame can be reduced, which makes the device excellent in mass production.

In one embodiment of the invention, a light reflection surface is formed on the translucent resin of the light emitting element so that the light beam emitted from the light emitting chip is reflected by the light reflection surface of the light emitting element to come incident into the light receiving chip.

According to this embodiment, when the height of the optical axis of the light emitting element is displaced from the height of the optical axis of the light receiving element, the height of the light reflection surface formed on the translucent resin constituting the light emitting element is adjusted so that the light beam from the light emitting element can be guided to the light receiving chip.

In one embodiment of the invention, a light reflection surface is formed on the translucent resin of the light receiving element so that the light beam emitted from the light emitting chip is reflected by the light reflection surface of the light receiving element to come incident into the light receiving chip.

According to this embodiment, when the height of the optical axis of the light emitting element is displaced from the height of the optical axis of the light receiving element, the height of the light reflection surface formed on the translucent resin of the light receiving element is adjusted so that the light beam from the light emitting element can be guided to the light receiving chip.

In one embodiment of the invention, the light beam emitted from the light emitting chip is reflected by a light reflection surface of the light emitting element to change the optical path direction into an opposite direction thereto so that the light beam is emitted from a rear surface of the light emitting element opposite to the light reflection surface of the light emitting element.

According to this embodiment, when the height of the optical axis of the light emitting element is different from a predetermined target height, the height of the light reflection surface formed on the translucent resin of the light emitting element is adjusted so that the height of the optical axis of the light emitting element can be set to the predetermined height.

The present invention also provides a manufacturing method for a transmission type photo interrupter, comprising:

mounting a plurality of light emitting chips on a lead frame having a connector terminal;

internally connecting the lead frame to each of the light emitting chips;

mounting a plurality of light receiving chips on the lead frame;

internally connecting the lead frame to each of the light receiving chips;

sealing each of the light emitting chips and each of the light receiving chips with translucent resin to form a plurality of light emitting elements and a plurality of light receiving elements;

folding the lead frame having the light emitting element and the light receiving element formed thereon so that the light emitting element and the light receiving element stand upright with respect to a surface of the lead frame in a state of facing each other;

sealing the light emitting element, the light receiving element, the lead frame, and at least a part of the connector terminal with light-shielding resin so that the light emitting element, the light receiving element, the lead frame and the connector terminal are integrally molded; and

cutting a tie bar, which connects and secures devices each having the light emitting element, the light receiving element, the lead frame and the connector terminal to the lead frame, so that the devices are separated into individual devices.

According to this invention, it becomes unnecessary to store the light emitting element, the light receiving element, the lead frame and the connector terminal in an armored case or an armour folder as in JP 07-193272A. Therefore, the number of assembly parts can be reduced. Further, it becomes unnecessary to perform hot welding for securing the lead frame to the armored case or the armour folder. Therefore, the assembly process can be simplified, which makes excellent mass production of the device. That is, according to the present invention, the number of assembly parts can be reduced and thereby the assembly process can be simplified, so that cost reduction can be achieved.

Also, the lead frame and a part of the connector terminal are all covered with light-shielding resin, and therefore the holding state of the lead frame and the connector can be strengthened much more.

In one embodiment of the invention, electronic equipment uses the above-stated transmission type photo interrupter.

According to the above structure, it is possible to manufacture at low costs electronic equipment such as copy machines and printers which uses the transmission type photo interrupter for detection of the presence of paper and detection of the edge of paper, because the transmission type photo interrupter of the present invention is used therefor which can reduce the number of assembly parts and simplify the assembly process.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1A is a side view showing a lead frame after cutting a tie bar in a transmission type photo interrupter according to the present invention;

FIG. 1B is a top view showing the lead frame after cutting the tie bar in the transmission type photo interrupter according to the present invention;

FIG. 2A is a side view showing a state in which the lead frame shown in FIGS. 1A and 1B is formed;

FIG. 2B is a top view showing the state in which the lead frame shown in FIGS. 1A and 1B is formed;

FIG. 3A is a side view showing a state in which the lead frame shown in FIGS. 2A and 2B is integrally molded up to a part of a connector terminal;

FIG. 3B is a top view showing the state in which the lead frame shown in FIGS. 2A and 2B is integrally molded up to the part of the connector terminal;

FIG. 3C is a cross sectional view showing the state in which the lead frame shown in FIGS. 2A and 2B is integrally molded up to the part of the connector terminal;

FIG. 4A is a side view showing the lead frame after cutting of the tie bar in the transmission type photo interrupter, which lead frame is different from that in FIGS. 1A and 1B;

FIG. 4B is a top view showing the lead frame after cutting of the tie bar in the transmission type photo interrupter, which lead frame is different from that in FIGS. 1A and 1B;

FIG. 5A is a side view showing a state in which the lead frame shown in FIGS. 4A and 4B is formed;

FIG. 5B is a top view showing the state in which the lead frame shown in FIGS. 4A and 4B is formed;

FIG. 6A is a side view showing a lead frame after cutting of the tie bar in the transmission type photo interrupter, which lead frame is different from those in FIGS. 1A and 1B and FIGS. 4A and 4B;

FIG. 6B is a top view showing the lead frame after cutting of the tie bar in the transmission type photo interrupter, which lead frame is different from those in FIGS. 1A and 1B and FIGS. 4A and 4B;

FIG. 7A is a side view showing a state in which the lead frame shown in FIGS. 6A and 6B is formed;

FIG. 7B is a top view showing the state in which the lead frame shown in FIGS. 6A and 6B is formed; and

FIG. 8 is a cross sectional view showing a structure of a conventional optical coupling device.

### DETAILED DESCRIPTION OF THE INVENTION

Hereinbelow, the present invention will be described in details in conjunction with embodiments with reference to the drawings.

### First Embodiment

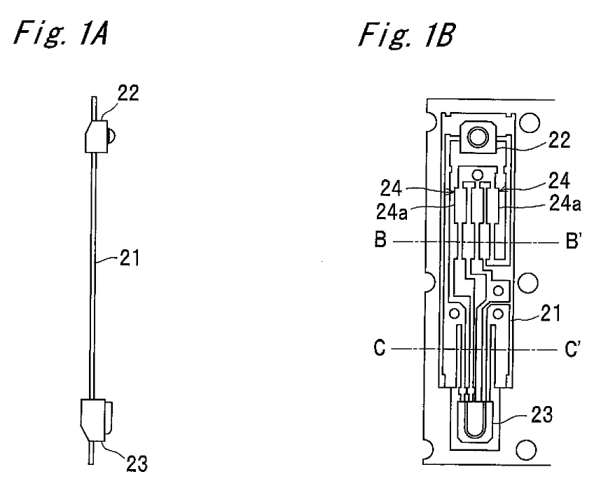

FIGS. 1A and 1B respectively show a side view and a top view of a lead frame after tie bar cutting of a transmission type photo interrupter according to the present embodiment. A lead frame 21 shown in FIGS. 1A and 1B is provided with a light emitting element 22, wherein a light emitting chip (not shown) is bonded to a lead frame 21 to be internally connected with wires such as gold wires, and is molded with translucent resin. Similarly, a light receiving chip (not shown) is bonded onto a same surface of the light emitting chip in the lead frame 21 so as to be internally connected with wires such as gold wires. Then the light receiving chip is molded with translucent resin so as to form a light receiving element 23. Further, an unnecessary part in the lead frame 21 is removed (tie-bar-cut). A connector terminal 24 is an input/output terminal of the light emitting chip and the light receiving chip to the outside.

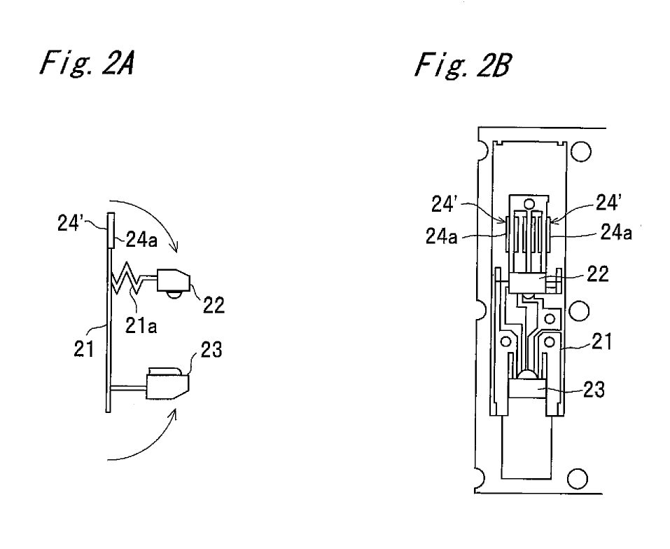

FIGS. 2A and 2B show the lead frame after being formed (folded). FIG. 2A is a side view of the lead frame and FIG. 2B is a top view thereof. In FIGS. 2A and 2B, the light emitting element 22 is folded clockwise in FIG. 2A with respect to the lead frame 21, while the light receiving element 23 is folded anticlockwise in FIG. 2A with respect to the lead frame 21. In this way, the light emitting element 22 and the light receiving element 23 stand straight in such a way that the light emitting chips thereof may face each other.

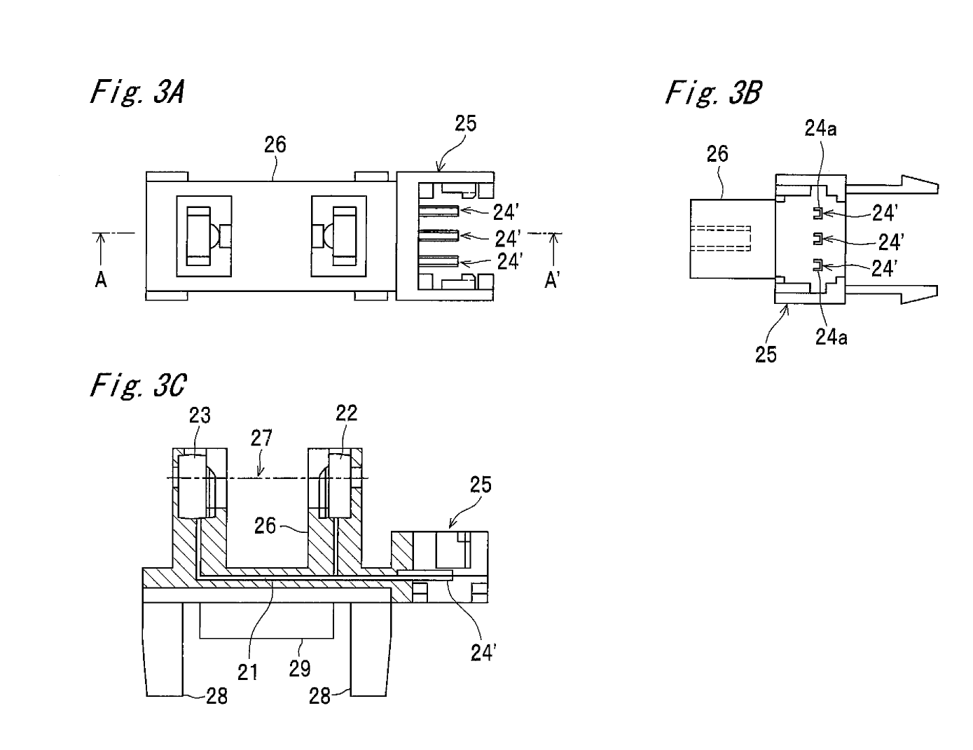

FIGS. 3A, 3B and 3C show the light emitting element 22, the light receiving element 23, the lead frame 21 and a part of a connector terminal 24′ which are integrally molded with use of light-shielding resin. It is to be noted that FIG. 3A is a top view of, FIG. 3b is a view seen from the side of the connector terminal 24′, and FIG. 3C is a cross sectional view taken along an arrow line A-A′ of FIG. 2A.

In FIG. 3C, the light emitting element 22 and the light receiving element 23 are covered with light-shielding resin 26 together with the lead frame 21, so that the light emitting element 22 and the light receiving element 23 are placed facing each other across an object passage 27. The connector terminal 24′ is provided so as to protrude toward the side of the light emitting element 22.

Description is hereinafter given of the structure of the transmission type photo interrupter as well as the manufacturing procedure thereof.

FIG. 1B shows the lead frame 21 mounted with the light emitting element 22 and the light receiving element 23. The lead frame 21 is formed with nickel-based alloy which has a rust preventing characteristic and high strength. The light emitting chip and the light receiving chip are mounted on the same surface of the lead frame 21 for one device, and are secured thereon through bonding. Then, the light emitting chip and the light receiving chip are connected to the lead frame 21 by gold wires, for example.

After the light emitting chip and the light receiving chip are mounted on the lead frame 21 as mentioned above, the light emitting chip and the light receiving chip are molded with translucent resin so as to form the light emitting element 22 and the light receiving element 23. Thereafter, an unnecessary part of the lead frame 21 is removed (tie bar cut).

Herein, a dashed line B-B′ shown in FIG. 1B represents a folding position when the lead frame 21 having the light emitting element 22 thereon is folded clockwise as shown in FIG. 2A. Further, a dashed line C-C′ shown in FIG. 1B represents a folding position when the lead frame 21 having the light receiving element 23 thereon is folded anticlockwise as shown in FIG. 2A (i.e., in a direction opposite to the folding direction of the light emitting element 22). Thus, the light emitting element 22 is faced with the light receiving element 23. In the present embodiment, the connector terminals 24 are located together on the side of the light emitting element 22 so as to electrically connect the lead frame 21 to the outside. The location of the connector terminals 24 may be on the side of the light receiving element 23 or other places.

More specifically, in a folding (forming) process, as shown in a FIG. 2A, the lead frame 21 on the side of the light emitting element 22 is folded along the dashed line B-B′, and the lead frame 21 on the side of the light receiving element 23 is folded along the dashed line C-C′. As the result, the light emitting element 22 and the light receiving element 23 stand upright in the state of facing each other. In the present embodiment, the light emitting element 22 is located on the outer side than the connector terminal 24 with respect to the dashed line B-B′ in the state before folding the lead frame 21 on the side of the light emitting element 22 along the dashed line B-B′. Thus, a distance from the light emitting element 22 to the dashed line B-B′ is longer than a distance from the connector terminal 24 thereto. In the case where the distance from the light emitting element 22 to the dashed line B-B′ is longer than a distance from the light receiving element 23 to the dashed line C-C′, the light emitting element 22 is different from the light receiving element 23 in height of their optical axes after the lead frame 21 is folded. In that case, in order to make both the optical axes identical height, the height of the optical axis of the light emitting element 22 is adjusted by folding the lead frame 21a on the side of the light emitting element 22 like bellows in a short cycle as shown in a FIG. 2A. Naturally, the height of the optical axis of the light receiving element 23 may be adjusted by using the lead frame 21 on the side of the light receiving element 23.

Both side sections 24a of each connector terminal 24 form part of a planar surface as shown in FIG. 1A. Those side sections 24a are folded approximately perpendicular to the surface of the connector terminal 24 in such a way that the connector terminal 24′ has a U-shaped cross section as shown in FIG. 3B. Thereby, the connector terminal 24′ is enhanced in strength.

Next, the light emitting element 22, the light receiving element 23, the lead frame 21 and a part of the connector terminal 24′ are molded with light-shielding resin. This integrates the light emitting element 22, the light receiving element 23, the lead frame 21 and the connector terminal 24′. The connector terminal 24′ formed in this way is surrounded by a connector 25 made of light-shielding resin.

Thus, the transmission type photo interrupter is completed to have a cross section as shown in FIG. 3C. In FIG. 3C, a portion molded by the light-shielding resin is the connector 25 and positioning hooks 28, 29 as well as a hatched portion.

In the present embodiment, as described above, the light emitting element 22, the light receiving element 23, the lead frame 21 and a part of the connector terminal 24′ are integrally molded by light-shielding resin. This makes it unnecessary to use the armour folder in the conventional optical coupling device disclosed in JP H07-193272A, so that the number of assembly parts can be reduced to achieve cost reduction.

The integral molding makes it unnecessary to employ an assembly process for storing the light emitting element 22 and the light receiving element 23 in the armour folder, and also a fixing process for securing the light emitting element 22, the light receiving element 23, the lead frame 21 and the connector terminal 24′, which have been integrated, to the armour folder by hot welding. Thus, the assembly process can be simplified to achieve cost reduction.

### Second Embodiment

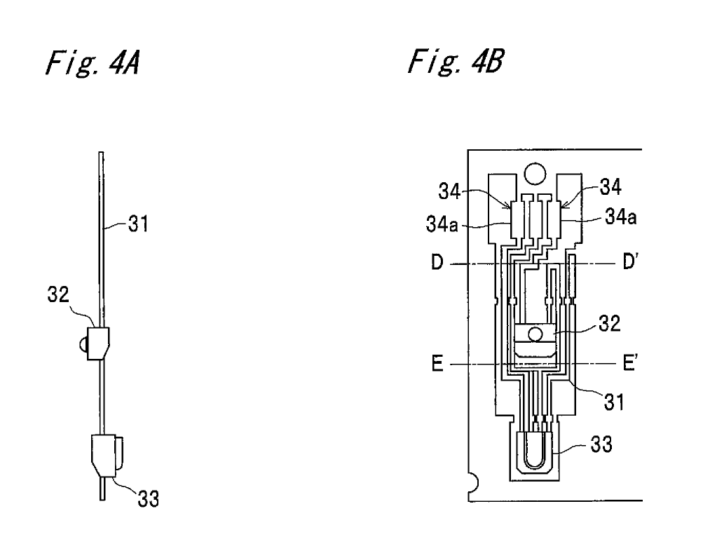

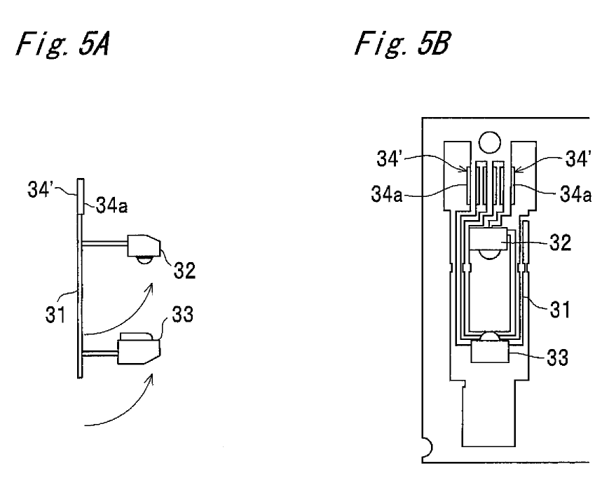

FIGS. 4A and 4B show a lead frame after tie-bar-cutting of a transmission type photo interrupter in the present embodiment. FIG. 4A is a side view of the lead frame and FIG. 4B is a top view thereof. FIGS. 5A and 5B show the above-stated lead frame after folding. FIG. 5A is a side view of the lead frame and FIG. 5B is a top view thereof. Hereinafter, description is mainly given of portions different from the first embodiment with reference to FIGS. 4A, 4B, 5A and 5B.

As shown in FIG. 4A, a light emitting chip (not shown) is mounted on an opposite surface of a lead frame 31 to the surface thereof on which the light receiving chip (not shown) is mounted. The light emitting chip and the light receiving chip are then molded with translucent resin to form a light emitting element 32 and a light receiving element 33, respectively. Then, both the light emitting element 32 and the light receiving element 33 are folded anticlockwise with respect to the lead frame 31, as shown in FIG. 5A. In this way, the light emitting element 32 and the light receiving element 33 stand upright in such a way that the light emitting chip and the light emitting chip face each other.

In this case, it is possible to shorten an interval between mounting positions of the light emitting element 32 and the light receiving element 33 in a state prior to folding, in comparison with the case of folding the elements in different directions each other as in the first embodiment. This is because the light emitting element 32 and the light receiving element 33 are respectively mounted on the front and rear surfaces of the lead frame 31 opposite to each other, as shown in FIG. 4A, so that the folding allows the light emitting element 32 and the light receiving element 33 to be moved in the same direction with respect to the surface of lead frame 31, as shown in a FIG. 5A. Thus, the frame size of the lead frame 31 can be reduced as compared with the case of the first embodiment. This leads to superior mass production.

In the present embodiment, before folding the lead frame, the light emitting element 32 and the light receiving element 33 are on the same side with respect to the connector terminal 34. Therefore, as shown in FIG. 4B, it becomes easily possible to approximately equalize a distance from the light emitting element 32 to the folding position D-D′ and a distance from the light receiving element 33 to the folding position E-E′. As a result, as shown in FIG. 5A, it becomes possible to set the heights of the optical axis of the light emitting element 32 and the light receiving element 33 in such a way that the heights thereof may become an identical predetermined height when the lead frame 31 is folded. As a result, it becomes unnecessary to adjust the heights of the optical axis of the light emitting element 32 or the light receiving element 33 as in the case of the first embodiment.

### Third Embodiment

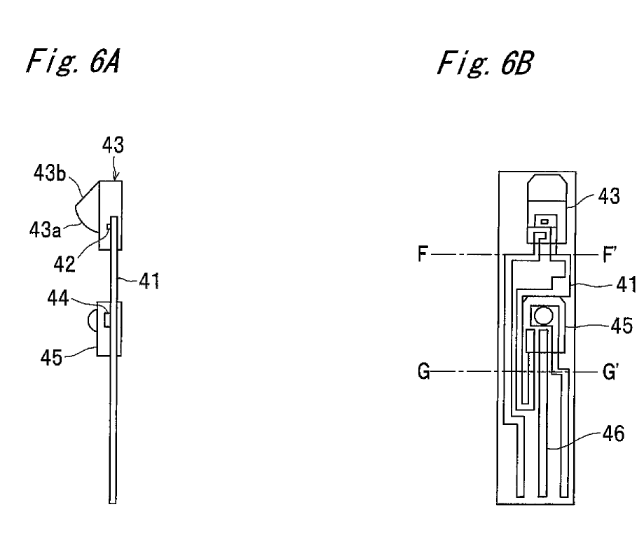

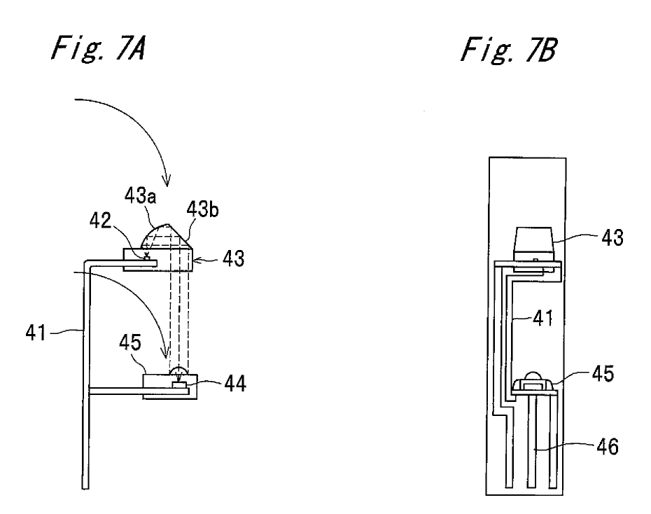

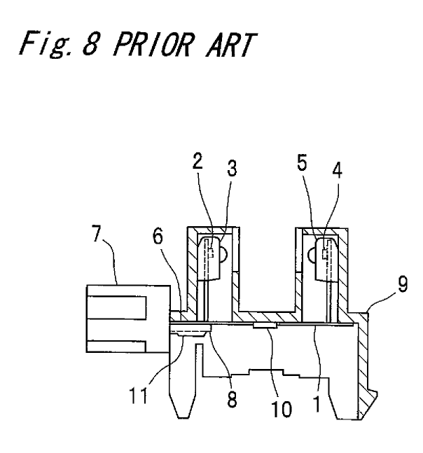

FIGS. 6A and 6B show views of a lead frame after tie bar cutting of a transmission type photo interrupter in the present embodiment. FIG. 6A is a side view of the lead frame. FIG. 6B is a top view of the lead frame. FIGS. 7A and 7B show the lead frame after folding (forming). FIG. 7A is a side view of the lead frame. FIG. 7B is a top view of the lead frame. Hereinafter, description is mainly given of the portions different from the first embodiment with reference to FIGS. 6A, 6B, 7A and 7B.

As shown in FIG. 6A, firstly, a light emitting chip 42 and a light receiving chip 44 are mounted on a same surface of a lead frame 41. In this way, it is not necessary to turn the lead frame 41 over during mounting of the light emitting chip 42 and the light receiving chip 44. This advantageously provides good workability.

Thereafter, the light emitting chip 42 and the light receiving chip 44 are molded with translucent resin to obtain a light emitting element 43 and a light receiving element 45. During this process, as shown in FIGS. 6A and 7A, a shape of the translucent resin in the light emitting element 43 is formed to have a first reflection surface 43a for reflecting a light beam from the light emitting chip 42 and a second reflection surface 43b for reflecting the light beam from the first reflection surface 43a. As shown in FIG. 7A, this makes it possible to reflect the light beam emitted from the light emitting chip 42 twice within the translucent resin (specifically, the light emitting element 43), and to emit it from the backside of the light emitting element 43. In the present embodiment, the sectional shape of the first reflection surface 43a in the light emitting element 43 is parabolic, but it may be planar instead.

In order to make the light beam emitted from the backside of the light emitting element 43 come incident into the light receiving chip 44, i.e., in order to make the light emitting chip 42 and the light receiving chip 44 face in the same direction, both the lead frame 41 on the side of the light emitting element 43 and the lead frame 41 on the side of the light receiving element 45 are folded (formed) clockwise in the same direction, as shown in FIG. 7A, so that the light emitting element 43 and the light receiving element 45 stand upright.

In the present embodiment, as in the case of the second embodiment, the light emitting element 43 and the light receiving element 45 are folded in the same direction with respect to the surface of the lead frame 41. In the state prior to the folding (forming), therefore, an interval between the mounting positions of the light emitting element 43 and the light receiving element 45 can be shortened in comparison with the case of folding them in opposite directions as in the case of the first embodiment. Thus, it becomes possible to reduce the frame size of the lead frame 41 as compared with the case of the first embodiment, which leads to superior mass production of the device.

The light emitting element 43 and the light receiving element 45 are on the same side with respect to the connector terminal 46. As shown in FIG. 6B, this makes it possible to approximately equalize a distance from the light emitting element 43 to the folding position F-F′ and a distance from the light receiving element 45 to the folding position G-G′. As a result, as shown in FIG. 7A, it becomes possible to set the heights of the optical axis of the light emitting element 43 and the light receiving element 45 in such a way that those heights become identical predetermined ones when the lead frame 41 is folded.

If there still exists a different between the height of the optical axis of the light emitting element 43 and the height of the optical axis of light receiving element 45 due to design of the lead frame 41, adjusting the height of the second reflection surface 43b of the translucent resin makes it possible to conform the height of the optical axis of the light emitting element 43 to the predetermined height.

In the present embodiment, the first reflection surface 43a and the second reflection surface 43b are provided on the translucent resin of the light emitting element 43. However, it is also possible to provide the first and second reflection surfaces on the translucent resin of the light receiving element 45 in such a way that a light beam incident into the light emitting element 45 is reflected by the first and second reflection surfaces to come incident into the light receiving chip 44.

It is greatly effective to apply the transmission type photo interrupter above-stated in the embodiments to the paper sensing devices for printers, copy machines or the like. Specifically, electronic equipment such as printers and copy machines has a paper teed function. Therefore, by mounting the transmission type photo interrupter on each paper feed mechanism, it becomes possible to know which paper feed mechanism a paper sheet has passed through to be processed so far. This makes it possible to smooth the processing in the electronic equipment. Moreover, even in the case where paper jam or other troubles occur, the transmission type photo interrupter has great effects since it can inform users which paper feed mechanism generates the paper jam.

The invention being thus described, it will be obvious that the invention may be varied in many ways. Such variations are not be regarded as a departure from the spirit and scope of the invention, and all such modifications as would be obvious to one skilled in the art are intended to be included within the scope of the following claims.

1. A transmission type photo interrupter, comprising:
a lead frame having a connector terminal;
a light emitting element having a light emitting chip and translucent resin, the light emitting chip being mounted on the lead frame, internally connected with the lead frame and sealed in the translucent resin; and
a light receiving element having a light receiving chip and translucent resin, the light receiving chip being mounted on the lead frame, internally connected with the lead frame and sealed in the translucent resin, wherein
the light emitting element, the light receiving element, the lead frame, and at least a part of the connector terminal are sealed with light-shielding resin so that the light emitting element, the light receiving element, the lead frame and the connector terminal are integrally molded.

2. The transmission type photo interrupter set forth in claim 1, wherein
the light emitting chip is mounted on a same surface of the lead frame as a surface thereof on which the light receiving chip is mounted, and
the light emitting element and the light receiving element has been rotated in opposite directions each other with respect to the lead frame surface so as to stand upright on the same surface of the lead frame, so that the light emitting chip and the light receiving chip face each other.

3. The transmission type photo interrupter set forth in claim 1, wherein
the light emitting chip is mounted on an opposite surface of the lead frame to a surface thereof on which the light receiving chip is mounted,
the light emitting element and the light receiving element have been rotated in a same direction with respect to the lead frame surface so as to stand upright on the same surface of the lead frame, so that the light emitting chip and the light receiving chip face each other.

4. The transmission type photo interrupter set forth in claim 1, wherein
the light emitting chip is mounted on a same surface of the lead frame as a surface thereof on which the light receiving chip is mounted,
the light emitting element and the light receiving element have been rotated in a same direction with respect to the lead frame surface so as to stand upright on the same surface of the lead frame, so that the light emitting chip and the light receiving chip face in a same direction.

5. The transmission type photo interrupter set forth in claim 4, wherein
a light reflection surface is formed on the translucent resin of the light emitting element so that the light beam emitted from the light emitting chip is reflected by the light reflection surface of the light emitting element to come incident into the light receiving chip.

6. The transmission type photo interrupter set forth in claim 4, wherein
a light reflection surface is formed on the translucent resin of the light receiving element so that the light beam emitted from the light emitting chip is reflected by the light reflection surface of the light receiving element to come incident into the light receiving chip.

7. The transmission type photo interrupter set forth in claim 4, wherein
the light beam emitted from the light emitting chip is reflected by a light reflection surface of the light emitting element to change the optical path direction into an opposite direction thereto so that the light beam is emitted from a rear surface of the light emitting element opposite to the light reflection surface of the light emitting element.

8. A manufacturing method for a transmission type photo interrupter, comprising:
mounting a plurality of light emitting chips on a lead frame having a connector terminal;
internally connecting the lead frame to each of the light emitting chips;
mounting a plurality of light receiving chips on the lead frame;
internally connecting the lead frame to each of the light receiving chips;
scaling each of the light emitting chips and each of the light receiving chips with translucent resin to form a plurality of light emitting elements and a plurality of light receiving elements;
folding the lead frame having the light emitting element and the light receiving element formed thereon so that the light emitting element and the light receiving element stand upright with respect to a surface of the lead frame in a state of facing each other;
sealing the light emitting element, the light receiving element, the lead frame, and at least a part of the connector terminal with light-shielding resin so that the light emitting element, the light receiving element, the lead frame and the connector terminal are integrally molded; and
cutting a tie bar, which connects and secures devices each having the light emitting element, the light receiving element, the lead frame and the connector terminal to the lead frame, so that the devices are separated into individual devices.

9. Electronic equipment using the transmission type photo interrupter set forth in claim 1.
